(19) United States
(12) Patent Application Publication
(10) Pub. No.: US 2004/0216675 A1
(43) Pub. Date: Nov. 4, 2004

(54) Deposited film forming method and apparatus

(75) Inventors: Hiroyuki Katagiri, Shizuoka (JP); Toshiyasu Shirasuna, Shizuoka (JP); Hideaki Matsuoka, Shizuoka (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISA, TOKYO (JP)

(21) Appl. No.: 10/833,028

(22) Filed: Apr. 28, 2004

(30) Foreign Application Priority Data
Apr. 30, 2003 (JP) 2003-125185
Apr. 30, 2003 (JP) 2003-125186

(51) Int. Cl. C23C 16/00

(52) U.S. Cl. 118/723 E

(57) ABSTRACT

A deposited film forming method and a deposited film forming apparatus are provided in which a cylindrical support is smoothly rotated, the sliding property is excellent, the corrosion resistance and the durability are high, and the nonuniformity in the electrophotographic characteristics is small.

The method comprises disposing a cylindrical support in a pressure-reducible reaction vessel, rotating the cylindrical support, introducing a source gas for deposited film formation into the reaction vessel using a source gas introduction means, heating the cylindrical support, applying a discharge energy for exciting the source gas, and forming a deposited film through plasma CVD while evacuating the interior of the reaction vessel, wherein the rotation of the cylindrical support is conducted by use of a rotation means provided with a nonrotating part comprising a sliding member having at least a sliding surface part at least a part of which is formed of a solid lubricating material.

### BACKGROUND OF THE INVENTION

1. Field of the Invention

The present invention relates to a deposited film forming method and an apparatus therefor based on a plasma CVD (Chemical Vapor Deposition) method suitable for forming a deposited film on a support, in particular a functional deposited film, yet in particular, a light-receiving member taking advantage of a non-monocrystalline deposited film including an amorphous or a polycrystalline film for use in a semiconductor device, an electrophotographic photosensitive member, a line sensor for image input, an image pickup device, a photovoltaic element and the like.

2. Related Background Art

As element members for use in semiconductor devices, electrophotographic photosensitive members, line sensors for image input, image pickup devices, photovoltaic elements, other various electronics elements, optical elements and the like, there have hitherto been proposed deposited films for use in semiconductors formed of amorphous silicon, for example, an amorphous silicon (a-SiH/X) compensated with hydrogen and/or halogen (for example, fluorine, chlorine and the like) and the like; some of the proposed deposited films have been in practical use. When these deposited film are formed, uniformity both in film thickness and in film characteristics is required. In this connection, for the purpose of making the film characteristics uniform, effective is provision of a device for making the plasma uniform with the aid of the method for supplying the source gas, the plasma CVD method and the like, and a device for rotating the member being formed. When the member being formed is rotated, the degradation of the operation life of the apparatus and the apparatus configuration are also crucial, and various types of apparatus configurations have been proposed for the purpose of rotating the member being formed. For example, Japanese Patent Publication No. H5-33814 discloses a configuration in which rolling elements are used for the bearing of a rotation shaft.

Deposited films have thitherto been made uniform with the aid of such devices; however, in these years, digitization and colorization come to demand the deposited film uniformity, needless to say, and additionally deposited films excellent in electrophotographic characteristics. Accordingly, the layer configuration of deposited films comes to be diversified. Additionally, the temperature during the deposited film formation comes to be an important factor in the deposited film formation, and hence it has become inevitable to form high quality deposition films by applying a greater thermal energy.

FIG. 2 is a schematic sectional view illustrating an example of a conventional deposited film forming apparatus. The apparatus shown in FIG. 2 comprises broadly a deposition unit 2100 and an evacuation unit 2200 for reducing the pressure of the interior of the reaction vessel 210. The interior of the deposition unit 2100 has a configuration such that there are arranged a cylindrical support 212, a support holder 217, a heater 213 for heating the support, a pipe 214 for introducing the source gas having an opening for introducing the source gas, a mixer 224 through the intermediary of a mass flow controller (not shown in the figure) for adjusting the flow rate of the source gas and a source gas inflow valve 230. Additionally, a high frequency electric power supply 216 is arranged through the intermediary of a high frequency matching box 215.

Additionally, in the bottom portion of the reaction vessel 210, there are arranged a driving device having a motor 220 for rotating the cylindrical support 212 and a driving gear 219, and a rotation device 218 having a rotation gear 218-1 and a rotation base 218-2. Additionally, in the rotation device, as the rotation bearing, used is a bearing 222 comprising a raceway ring and rolling elements, and provided is a holding stay 231 for holding the bearing 222 and the heater 213 for heating the support. The cylindrical support 212 is fixed to a support holder 217, and made rotatable by arranging a rotation pedestal 221 on the rotation base 218-2. The evacuation unit 2200 has a configuration such that an evacuation pipe 228 is provided with a vacuum gauge 225 and an evacuation main valve 227, and the inside pressure of the reaction vessel 210 can be maintained at a predetermined pressure by use of a vacuum pump unit 229 comprising a vacuum pump such as a rotary pump, a mechanical booster pump and the like. With the aid of the deposited film forming method using such a conventional deposited film forming apparatus, it has become possible to obtain deposited films having characteristics and uniformity practical to some extent.

However, such conventional deposited film forming apparatuses is associated with a problem that in the case of the products which require large area and relatively thick deposition thickness, such as the electrophotographic photosensitive member, a large amount of powder byproducts and broken pieces of a deposited film are generated and intrude into the bearing portion to adversely affect the rotation. Additionally, in the case where a highly corrosive cleaning gas is used in order to remove the powder byproducts and broken pieces of a deposited film after the formation of the deposited film, there also remains a problem that the bearing itself is corroded. Furthermore, the actual situation is such that the cleaning treatment step after the deposited film formation has to be conducted under more severe conditions because the process yield is to be improved and the tact time is intended to be reduced.

Under these circumstances, the load to be burdened on the deposited film forming apparatus becomes larger, and accordingly there occurs an adverse effect that the thermal expansion of the bearing of the ball bearing used as a means for rotating the cylindrical support during the deposited film formation results in uneven rotation period, as the case may be. Additionally, when the concentration of the cleaning gas is increased for the purpose of reducing the cleaning treatment time, the corrosion of the bearing members including the ball bearing proceeds to cause adverse effects such as the rotation axis fluctuation as the case may be.

Although a method may be conceivable in which in consideration of the thermal expansion of the bearing members of the ball bearing, the dimension involved in the ball bearing is determined to secure smooth rotation when the ball bearing is heated, and the adoption of such a method causes the dimensional tolerance to become large and adversely affects the precision of the rotation. Additionally, when a deposited film with a multilayer configuration made to have functions is formed, the deposition temperatures for the respective layers are different in a diversified manner. Accordingly, the shape variation of the bearing members caused by the thermal expansion also becomes complicated, and hence the fact is that merely regulating the dimension can hardly actualize the smooth rotation for all the layers.

Additionally, metallic materials having a high corrosion resistance have hitherto been used as a countermeasure against the corrosion caused by the cleaning gas; however, these metallic materials are expensive and the progress of the corrosion thereof cannot necessarily be suppressed completely.

As described above, if the rotation precision is degraded or the bearing members are corroded and hence no smooth rotation can be effected, for example, sometimes the rotational fluctuation of the cylindrical support occurs as described above. In conventional electrophotographic devices, the use of the electrophotographic photosensitive members formed under the conditions involving the slight fluctuation of the rotation axis has caused no problems from a practical standpoint. However, in recent high quality color image devices, the resolution is improved. Consequently, when the electrophotographic photosensitive members formed under the conditions involving the slight rotational fluctuation are used, the uneven electrophotographic characteristics of the electrophotographic photosensitive members become noticed visually as the case may be.

### SUMMARY OF THE INVENTION

It is, therefore, an object of the present invention to provide a deposited film forming method and a deposited film forming apparatus which can overcome the conventional problems and rotate the substrate stably and smoothly, and consequently can manufacture stably and with a high process yield electrophotographic photosensitive members which provide high quality images with less image defect and are easy to use.

Specifically, according to a first aspect of the present invention, there is provided a deposited film forming method which comprises disposing a cylindrical support in a pressure-reducible reaction vessel, rotating the cylindrical support, introducing a source gas for deposited film formation into the reaction vessel using a source gas introduction means, heating the cylindrical support, applying a discharge energy for exciting the source gas, and forming a deposited film through plasma CVD while evacuating the interior of the reaction vessel, wherein the rotation of the cylindrical support is conducted by use of a rotation means provided with a nonrotating part comprising a sliding member having at least a sliding surface part at least a part of which is formed of a solid lubricating material.

According to a second aspect of the present invention, there is provided a deposited film forming apparatus which comprises a pressure-reducible reaction vessel, a setting means for setting a cylindrical support in the reaction vessel, a rotation means for rotating the cylindrical support, an introduction means for introducing a source gas for deposited film formation into the reaction vessel, a heating means for heating the cylindrical support, an application means for applying a discharge energy for exciting the source gas, and an evacuation means for evacuating the interior of the reaction vessel, wherein the rotation means comprises a rotating part, and a nonrotating part comprising a sliding member having at least a sliding surface part, and a solid lubricating material is provided in at least a portion of the sliding surface part.

In the present invention, it is preferable that the sliding member has a cylindrical shape.

### BRIEF DESCRIPTION OF THE DRAWINGS

FIG. 1 is a schematic sectional view of a deposited film forming apparatus adopting the deposited film forming method of the present invention;

FIG. 2 is a schematic sectional view of a conventional deposited film forming apparatus;

FIG. 3 a schematic view illustrating the layer configuration of an amorphous silicon electrophotographic photosensitive member;

FIG. 4A is a sectional view illustrating the shape of a bearing formed of a solid lubricating material and FIG. 4B is an oblique perspective view thereof;

FIG. 5A is a sectional view illustrating the shape of a conventional ball bearing and FIG. 5B is an oblique perspective view thereof;

FIG. 6 is a schematic sectional view of a rotation means of the deposited film forming apparatus of the present invention; and

FIG. 7A is a sectional view illustrating the shape of a cylindrical supporting member, and FIG. 7B is an oblique perspective view thereof.

### DESCRIPTION OF THE PREFERRED EMBODIMENTS

The present inventors have diligently investigated the method for attaining smooth rotation and paid attention to a solid lubricating material as a material high in lubricating property. The solid lubricating material is characterized in that the solid lubricating material has a lamellar lattice structure and accordingly itself is fusion bonded to the surface of an opposite member so that the solid lubricating material serves to reduce the frictional resistance of the sliding part; thus the solid lubricating material is an optimal material for attaining smooth rotation. Additionally, the solid lubricating material has a thermal expansion coefficient approximately comparable to those of metals as far as the thermal expansion is concerned, but as described above, serves to reduce the frictional resistance, so that the solid lubricating material can hardly cause adverse effects such as scratching. On the other hand, as far as corrosion is concerned, the solid lubricating material is a self-lubricating material, and hence the sliding surface of the solid lubricating material is always renewed, so that corrosion has been found to affect the solid lubricating material to a very small extent. The use of the solid lubricating material for the sliding part for rotation has been found to make it possible to cope with the variations in the deposited film formation conditions and to actualize smooth rotation.

Additionally, the solid lubricating material permits optionally setting the shape thereof so that processing can be applied to obtain a shape thereof in compliance with the intended purpose. The solid lubrication material can be used in any portions, and additionally, the number of the portions provided with the sold lubricating material can be increased to improve the precision of the rotation axis by suppressing the rotational fluctuation and to increase the clearance between the solid lubricating material and the opposite member, resulting in an effect of improving the rotation precision.

Now, description will be made below on the embodiments of the present invention.

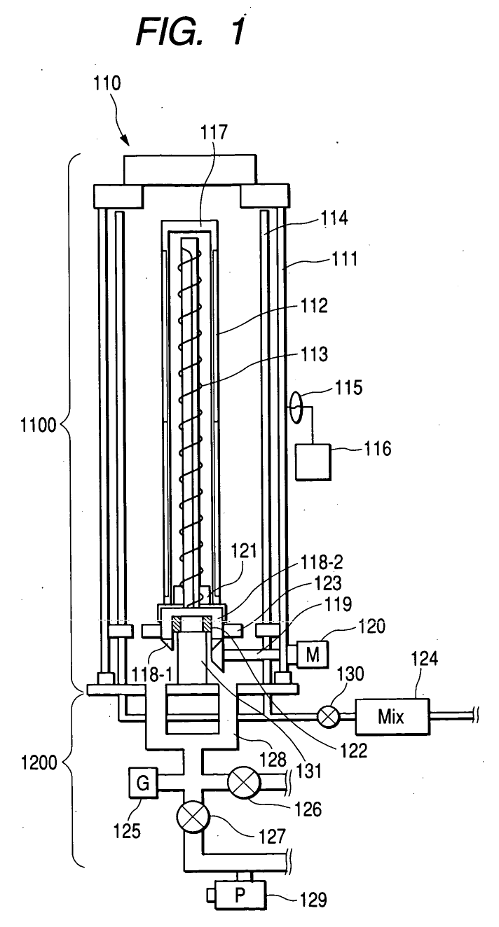

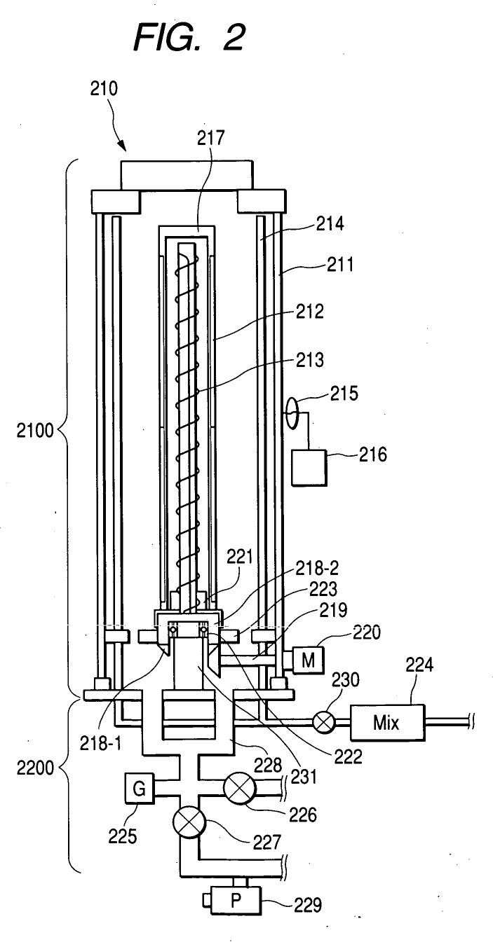

FIG. 1 is a schematic sectional view of an example of a deposited film forming apparatus used in the present invention for photosensitive members in which apparatus a radio frequency (RF) band high frequency electric power supply is used and the RF plasma chemical vapor deposition (CVD) method is applied.

The apparatus comprises broadly a deposition unit 1100 and an evacuation unit 1200 for reducing the pressure of the interior of the reaction vessel 110. The interior of the deposition unit 1100 has a configuration such that there are arranged a cylindrical support 112, a support holder 117, a heater 113 for heating the support, a pipe 114 for introducing a source gas having an opening for introducing the source gas, a mixer 124 through the intermediary of a mass flow controller (not shown) for adjusting the flow rate of the source gas and a source gas inflow valve 130. Additionally, a high frequency electric power supply 116 is arranged through the intermediary of a high frequency matching box 115.

Additionally, in the bottom portion of the reaction vessel 110, there are arranged a driving means having a motor 120 for rotating the cylindrical support 112 and a driving gear 119, and a rotation means 118 provided with a rotation gear 118-1, a rotation base 118-2, a holding stay 131, and a solid lubricating material 122 intervening as a bearing.

In the present invention, as the method for transmitting the driving force for rotation, either of the following two methods is effective: one in which rotation is conducted through the intermediary of a gear by arranging a driving shaft on the side of the deposition unit 1100 and the other in which a shaft for rotation is arranged coaxially with the cylindrical support 112 from either the bottom face or the top face of the reaction vessel 110 to rotate either the top end or the bottom end of the support holder 117; however, actually, suitable for the present invention is a method capable of simplifying the configuration in which method a driving shaft is arranged from the side of the deposition unit 1100 to rotate the cylindrical support 112 through the intermediary of the driving gear 119 and the rotation means 118. Additionally, when a rotation shaft for rotating the support holder 117 is formed, as the method for arranging the driving motor 120, effective is either a method in which the rotation shaft is arranged coaxially or on a parallel axis offset by an intervening gear or a method in which the rotation shaft is arranged perpendicularly to the rotation axis of the cylindrical support 112 through the intermediary of a gear.

In the present invention, the solid lubricating material 122 is fixed to the holding stay 131 so as to be nonrotatable, so that the outer peripheral surface of the solid lubricating material 122 and the inner peripheral surface of the rotation base 118-2 form a sliding surface part. Additionally, examples of the elements contained in the solid lubricating material 122 include tungsten (W), sulfur (S), carbon (C), boron (B) and nitrogen (N); however, in view of the deposited film forming conditions, it is preferable that the thermal expansion coefficient is small and can efficiently display the lubricating property in the atmosphere at 200° C. or more and 500° C. or less; accordingly, optimally it is preferable the solid lubricating material is a material containing at least one of tungsten and sulfur. Additionally, the application place of the solid lubricating material 122 can be any sliding surface portions either inside or outside the pressure-reducible reaction vessel, and simultaneous application to a plurality of portions is further effective.

In the present invention, as the opposite member forming a sliding surface portion with the solid lubricating material 122, stainless steel, copper, nickel and alloys thereof, all excellent in sliding property, are suitable among metallic materials. Among these suitable materials, stainless steel material is most suitable in view of the production cost and mechanical strength.

The cylindrical support 112 is fixed to the support holder 117, a rotation pedestal 121 is arranged on the rotation gear 118, and thus the use of the rotation means makes it possible to rotate the cylindrical support 112.

In the present invention, the rotation number of the cylindrical support 112 can be made larger than heretofore, because the use of the solid lubricating material 122 makes it possible to reduce the rotational fluctuation. However, when the rotation is too fast, the rotational fluctuation of the cylindrical support 112 sometimes becomes large in a subtle manner, while when the rotation is too slow, the effect of the rotation may become small, so that the rotation number is suitably 1 rpm or more and 20 rpm or less, and most suitably 1 rpm or more and 5 rpm or less.

Now, the configuration of the evacuation unit 1200 is such that an evacuation pipe 128 is provided with a vacuum gauge 125 and an evacuation main valve 127, and the inside pressure of the reaction vessel 110 is maintained at a predetermined pressure by use of a vacuum pump unit 129 comprising a vacuum pump such as a rotary pump, a mechanical booster pump and the like.

Now, description will be made below on an example of procedure for the deposited film forming method based on the apparatus shown in FIG. 1.

The support holder 117 to which the cylindrical support 112 is fixed is arranged in the reaction vessel 110, and the interior of the reaction vessel 110 is evacuated by means of the vacuum pump unit 129. Successively, a gas (for example, Ar or He) needed for heating the cylindrical support 112 is introduced into the interior of the reaction vessel 110 through the intermediary of the mixer 124 and the gas introduction pipe 114, and the inside pressure of the reaction vessel 110 is adjusted to be a predetermined pressure by means of the vacuum pump unit 129 and the evacuation main valve 127 while monitoring the vacuum gauge 125.

Then, when the predetermined pressure has been attained, the temperature of the cylindrical support 112 is regulated to be a desired temperature falling within the range from 200° C. to 450° C., and more preferably from 250° C. to 350° C., by means of the heater 113 for heating the support.

After the preparation for the deposited film formation has been completed through the above described procedure, the deposited film formation is conducted on the cylindrical support 112. First, a gas for dilution and a source gas for deposited film formation were introduced into the interior of the reaction vessel 110 through the mixer 124, and the flow rate of the source gas is adjusted so as to be a desired value. In this case, the opening extent of the main valve 127 is adjusted by monitoring the vacuum gauge 125 so as to set the inside pressure of the reaction vessel 110 to be a desired value falling within the range from 13.3 mPa to 1,330 Pa. When the inside pressure is stabilized, the high frequency electric power supply 116 is set at a desired electric power. Then, for example, by use of an RF electric power supply having a frequency of 13.56 MHz, the high frequency electric power is supplied to a cathode 111 through the high frequency matching box 115 to generate a high frequency glow discharge. The discharge energy decomposes the source gas introduced into the interior of the reaction vessel 110 to form a desired deposited film on the cylindrical support 112.

The cylindrical support 112 is rotated for the purpose of forming a uniform deposited film at the stage of forming the deposited film or for the purpose of performing uniform heating at the stage of heating the cylindrical support 112. The motor 120 is driven to rotate and thereby the rotation base 118-2 for which the driving gear 119 and the rotation pedestal 121 are arranged is rotated at a rotational speed of 1 rpm to 20 rpm. When the rotation number of a cylindrical substrate is too large at the time of plasma processing, the rotation axis fluctuation caused by rotation may become large, while when the rotation number of a cylindrical substrate is too small at the time of plasma processing, the effect provided by the rotation may become small. Accordingly, the rotation number of a cylindrical substrate at the time of plasma processing is further preferably 1 rpm or more and 10 rpm or less, and optimally 1 rpm or more and 5 rpm or less. At this time, the outer periphery of the solid lubricating material 122, as a bearing, forms a sliding surface portion with the inner surface of the rotation base 118-2. The rotation is continued until the completion of the deposited film formation. In this way, a deposited film is formed on the cylindrical support 112. As the source gas used at the time of deposited film formation, gases for amorphous silicon formation such as silane (SiH₄), disilane (Si₂H₆), silicon tetrafluoride (SiF₄) and disilicon hexafluoride (Si₂F₆), or mixed gases thereof are effectively used. As the diluting gas, hydrogen (H₂), argon (Ar), helium (He) and the like are used effectively. Additionally, as the gas for improving the characteristics such as varying the band gap of the deposited film, there are effectively used nitrogen (N₂), oxygen (O₂), nitrogen-containing compound gases such as ammonia (NH₃), oxygen-containing compound gases such as nitrogen monoxide (NO), nitrogen dioxide (NO₂), dinitrogen oxide (N₂O), carbon monoxide (CO) and carbon dioxide (CO₂), hydrocarbon gases such as methane (CH₄), ethane (C₂H₆), ethylene (C₂H₄), acetylene (C₂H₂) and propane (C₃H₈), fluorine-containing compound gases such as germanium tetrafluoride (GeF₄) and nitrogen trifluoride (NF₃), and mixtures thereof.

Similarly, effective is the simultaneous introduction of dopant gases such as diborane (B₂H₆), boron trifluoride (BF₃) and phosphine (PH₃) into the discharge space for the purpose of doping.

After completion of the deposited film formation, the source gas supply and the high frequency electric power supply are terminated, and the evacuation main valve 127 is fully opened to evacuate the interior of the reaction vessel 110. The interior of the reaction vessel 110 and the interior of the gas introduction pipe 114 are then purged with a purging gas (for example, an inert gas such as argon and/or N₂). After completion of the purging, the inside pressure of the reaction vessel 110 is recovered to atmospheric pressure by using an inert gas such as Ar and/or N₂ gas, and then the cylindrical support 112 on which a deposited film is formed is taken out from the reaction vessel 110. Then, a dummy support is placed inside the reaction vessel 110, and the interior of the reaction vessel 110 is subjected to cleaning treatment.

In the present invention, the heater 113 for heating the support is not particularly limited as long as it is usable in vacuum, and specific examples thereof include electric resistance heating elements such as a sheath heater, a plate heater, a ceramic heater and a carbon heater; thermal radiation lamp heating elements such as a halogen lamp and an infrared lamp; and heating elements based on a heat exchanger using a liquid or a gas as a heating medium. As the material for the surface of the heater 113 for heating the support, there can be used metals such as stainless steel, nickel, aluminum and copper; ceramic; and heat-resistant polymer and the like.

In the present invention, examples of the usable cleaning gases include CF₄, CF₄/O₂, SF₆, ClF₃ (chlorine trifluoride); however, in the present embodiment, ClF₃ (chlorine trifluoride) is effective for the purpose of shortening the cleaning time. Additionally, in the present embodiment, it is effective to adjust the concentration of the cleaning gas by use of an inert gas for dilution; examples of the introduced inert gas include He, Ne and Ar, and among these preferably used is Ar.

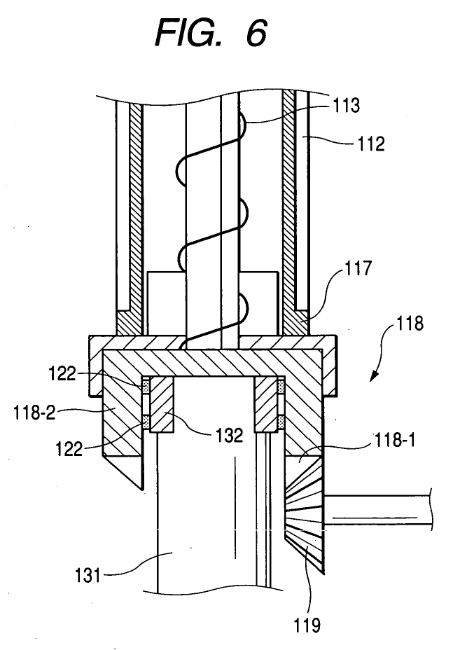

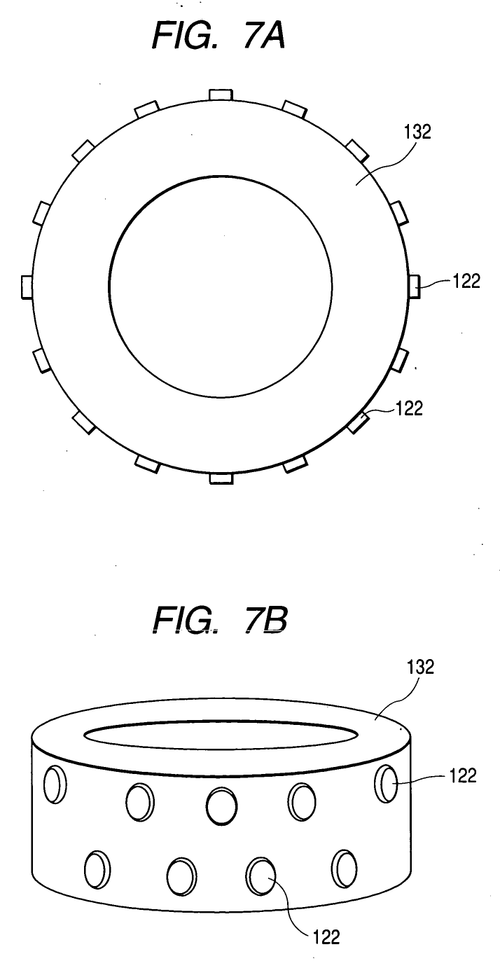

FIG. 6 is a schematic longitudinal sectional view illustrating the rotation means arranged in the vacuum treatment apparatus. FIGS. 7A and 7B are schematic views showing, as an example, members made of the solid lubricating material arranged in the cylindrical supporting member provided in the rotation means. Now, turning to the description of FIG. 6, the cylindrical supporting member 132 is formed in a cylindrical shape with, for example, stainless steel, copper, nickel, alloys of these metals and the like, and the inner periphery of the cylindrical supporting member 132 is fixed to the top end of the holding stay 131. Incidentally, for the material for the cylindrical supporting member 132, stainless steel is most suitable in consideration of the machining cost and mechanical strength.

On the sliding surface that is the outer peripheral surface of the cylindrical supporting member 132, a plurality of the members made of the solid lubricating material 122 are arranged respectively with predetermined intervals therebetween as shown in FIGS. 7A and 7B. The respective members made of the solid lubricating material 122 are fixed on the sliding surface of the cylindrical supporting member 132; examples of the method for fixing the members made of the solid lubricating material 122 include a driving method and a screwing method.

Accordingly, the rotation means 118 uses the cylindrical supporting member 132 having the members made of the solid lubricating material 122 arranged on the sliding surface facing the rotation base 118-2 as the bearing for rotatably supporting the rotation base 118-2.

Additionally, for the rotation base 118-2 against which the members made of the solid lubricating material 122 are made to slide, stainless steel, copper, nickel and alloys of these metals, which have a relatively good sliding property, are suitable among metallic materials. Incidentally, as the material for the rotation base, stainless steel is most suitable in consideration of the machining cost and mechanical strength.

Thus, the cylindrical support 112 is fixed to the support holder 117, and is made to rotate about the supporting axis together with the support holder 117 in such way that the rotation base 118-2 slides against the members made of the solid lubricating material 122 arranged in the cylindrical supporting member 132.

Now, further detailed description will be made below on the present invention on the basis of experimental examples and examples.

### EXAMPLES

### Example 1

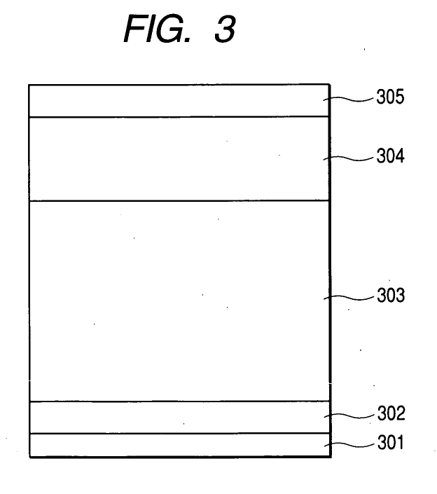

By using a deposited film forming apparatus of the configuration shown in FIG. 1, a deposited film was formed on the cylindrical support made of aluminum of 80 mm in outside diameter, 358 mm in length, and 5 mm in wall thickness, under the conditions shown in Table 1, and thus an amorphous silicon electrophotographic photosensitive member having a layer configuration shown in FIG. 3 was formed. In this case, the high frequency electric power supply used was a 13.56 MHz RF electric power supply. Incidentally, in FIG. 3, reference numerals 301, 302, 303, 304 and 305 denote the cylindrical support, a lower blocking layer (a first layer), a first photoconductive layer (a second layer), a second photoconductive layer (a third layer), and a surface protection layer (a fourth layer), respectively.

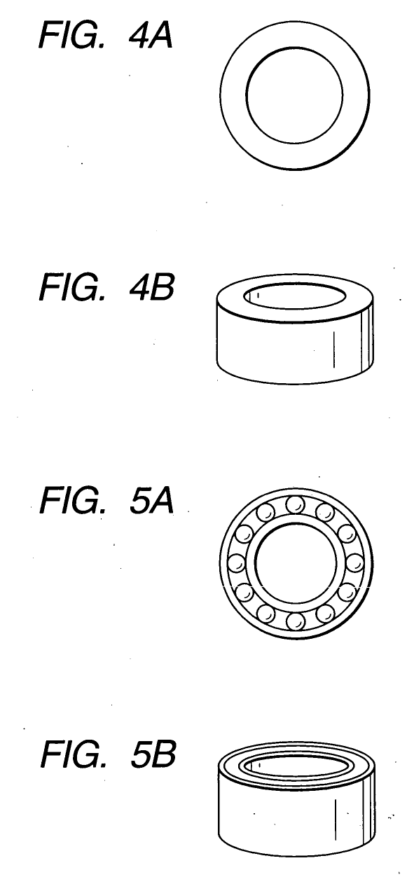

As shown in Table 2, as the solid lubricating material, a material containing tungsten disulfide (WS₂) (FWD-430L (trade name); manufactured by Fuji Dice Co., Ltd.) was used and worked into a bearing member of the shape as shown in FIGS. 4A and 4B. Additionally, stainless steel (SUS316L) was used for the rotation base 118-2 which was the opposite member in the sliding portion against the bearing member. As the cleaning gas used for cleaning treatment, ClF₃ diluted with Ar was used; in terms of one cycle consisting of the formation of a deposited film and the cleaning, 20 cycles of operation were performed; the deposited film forming apparatus used for the above described formation and the electrophotographic photosensitive members formed were evaluated under the conditions described below. The results thus obtained are shown in Table 3 under the heading of Example 1. Here, it should be noted that the rotational speed was fixed at 1 rpm.

### Example 2

As shown in Table 2, the deposited film formation and the cleaning treatment were carried out in the same manner as in Example 1 with the exception that as the solid lubricating material, a material containing carbon (C) (BGN6040 (trade name); manufactured by Fuji Dice Co., Ltd.) was used and worked into a bearing member of the shape as shown in FIGS. 4A and 4B; and the evaluation similar to that in Example 1 was performed. The results thus obtained are shown in Table 3 under the heading of Example 2.

### Example 3

As shown in Table 2, in Examples 3-1 and 3-2 were used phosphor bronze as a copper (Cu) material and HASTELLOY (trade name; available from Haynes International, Inc.) as a nickel (Ni) material, respectively, as the material for the rotation base 118-2 shown in FIG. 1 that is the member in the sliding portion opposite to the members made of the solid lubricating material. The deposited film formation and the cleaning treatment were carried out in the same manner as in Example 1 with the exception for the above mentioned material change, and the evaluation similar to that in Example 1 was performed. The results thus obtained are shown in Table 3 under the headings of Examples 3-1 and 3-2.

### Example 4

As shown in Table 2, the deposited film formation and the cleaning treatment were carried out in the same manner as in Example 1 with the exception that as the cleaning gas in the cleaning treatment a mixed gas prepared by mixing CF₄ with O₂ was used; and the evaluation similar to that in Example 1 was performed. The results thus obtained are shown in Table 3 under the heading of Example 4.

### Comparative Example

The deposited film formation and the cleaning treatment were carried out in the same manner as in Example 1 with the exception that as the bearing, a conventional ball bearing using stainless steel for rolling elements having the shape shown in FIGS. 5A and 5B was used; and the evaluation similar to that in Example 1 was performed. The results thus obtained are shown in Table 3 under the heading of Comparative Example. It should be noted that in the present comparative example, the abrasion quantity was not evaluated because no solid lubricating material was used.

TABLE 1

| | | | Substrate | | Supplied | Film |
|---|---|---|---|---|---|---|
| | | Flow Rate | Temper- | Inside | Electric | Thick- |
| | Source | (ml/min | ature | Pressure | Power | ness |
| Layer | Gas | (normal)) | (° C.) | (Pa) | (mW/cm³) | (μm) |
| First | SiH₄ | 100 | 250 | 60 | 10 | 3 |
| layer | H₂ | 600 | | | | |
| | NO | 5 | | | | |
| | B₂H₆ | 1500 ppm | | | | |
| | | (on the | | | | |
| | | basis of | | | | |
| | | SiH₄) | | | | |
| Second | SiH₄ | 100 | 270 | 73 | 15 | 20 |
| layer | H₂ | 800 | | | | |
| | B₂H₆ | 0.3 ppm | | | | |
| | | (on the | | | | |
| | | basis of | | | | |
| | | SiH₄) | | | | |
| Third | SiH₄ | 100 | 270 | 73 | 15 | 10 |
| layer | H₂ | 800 | | | | |
| Fourth | SiH₄ | 30 | 250 | 67 | 10 | 0.5 |
| layer | CH₄ | 600 | | | | |

Evaluations

(Sliding Performance)

The support holder to which the cylindrical support was fixed was rotated, and the torque at the time of rotation was measured at the initial stage and at the stage of completion of the 20 cycles of operation; thus the sliding performance was evaluated as follows.

A . . . No variation from the initial stage

B . . . Increase of the torque by less than 10% from the initial stage

C . . . Increase of the torque by 10% or more and less than 20% from the initial stage

(Abrasion Quantity)

The support holder to which the cylindrical support was fixed was rotated, and the volume of the solid lubricating material was measured at the initial stage and at the stage of completion of the 20 cycles of operation; thus the abrasion quantity caused by the rotation was measured and the evaluation was conducted as follows.

A . . . Volume decrement by less than 1% from the initial stage

B . . . Volume decrement by 1% or more and less than 5% from the initial stage

C . . . Volume decrement by 5% or more from the initial stage

(Exterior Appearance of Bearing)

On completion of the 20 cycles of operation, the corrosion condition of the sliding surface of the bearing was observed using a metallurgical microscope.

A . . . No corrosion and good condition

B . . . Partial corrosion observed

C . . . Whole corrosion observed

(Rotational Axis Fluctuation Quantity at the Time of Rotation)

The rotational axis fluctuation at the top end of the support holder to which the cylindrical support was fixed was measured at the initial stage and at the stage of completion of the 20 cycles of operation; thus the variation of the rotational axis fluctuation was measured.

A . . . No variation from the initial stage

B . . . Rotational axis fluctuation increase by less than 10% from the initial stage

C . . . Rotational axis fluctuation increase by 10% or more and less than 20% from the initial stage

(Electric Potential Uniformity)

The above formed electrophotographic photosensitive member was charged to a dark surface-potential (450 V), and the potential distribution along the circumferential direction was measured to obtain the difference between the maximum and the minimum values. This way of measurement was repeated at five (5) locations in the lengthwise direction of the electrophotographic photosensitive member, and the maximum of the differences determined for the five (5) locations was defined as the circumferential potential nonuniformity. The circumferential potential nonuniformity was measured at the initial stage of the deposited film formation and on completion of the 20 cycles of operation, and accordingly comparison and evaluation were performed.

A . . . Excellent without variation from the initial stage

B . . . Good with variation less than 10% from the initial stage

C . . . No practical problems with variation by 10% or more from the initial stage

(Overall Evaluation)

The overall evaluation grading was made on the basis of the following standards in terms of the above-described evaluation items.

A . . . All items graded as A

B . . . At least one item graded as B

C . . . At least one item graded as C

TABLE 2

| | | Opposite | |
|---|---|---|---|
| | Bearing | Member | Cleaning Gas |
| Example 1 | Solid lubricating | SUS316L | ClF₃ (diluted |
| | material: WS₂ | | with Ar) |
| Example 2 | Solid lubricating | SUS316L | ClF₃ (diluted |
| | material: C | | with Ar) |
| Example 3-1 | Solid lubricating | Cu | ClF₃ (diluted |
| | material: WS₂ | | with Ar) |
| Example 3-2 | Solid lubricating | Ni | ClF₃ (diluted |
| | material: WS₂ | | with Ar) |
| Example 4 | Solid lubricating | SUS316L | CF₄/O₂ |
| | material: WS₂ | | |
| Comparative | Rolling element: | SUS316L | ClF₃ (diluted |
| Example | stainless steel | | with Ar) |

TABLE 3

| | | | Exterior | | | |
|---|---|---|---|---|---|---|
| | | | Appearance | Rotational | Electric | |
| | Sliding | Abrasion | of | Axis | Potential | Overall |
| | Performance | Quantity | Bearing | Fluctuation | Uniformity | Evaluation |
| Example 1 | A | A | A | A | A | A |
| Example 2 | B | B | A | A | A | B |
| Example 3-1 | A | A | B | A | A | B |
| Example 3-2 | A | A | A | A | A | A |
| Example 4 | A | A | A(*) | A | A | A |
| Comparative | B | — | C | B | C | C |
| Example | | | | | | |

(*)Better than the other examples as far as the exterior appearance of the bearing was concerned.

As can be clearly seen from Table 3, excellent results have been obtained by use of the deposited film forming method and apparatus of the present invention.

### Example 5

The means shown in FIG. 6 was used as the rotation means of the deposited film forming apparatus shown in FIG. 1 to form an Amorphous silicon electrophotographic photosensitive member having the layer configuration shown in FIG. 3 was formed on a cylindrical substrate made of Al (aluminium) of 80 mm in outside diameter, 358 mm in length and 5 mm in wall thickness, under the conditions shown in Table 1.

The electrophotographic photosensitive member was formed on the cylindrical support 301 in such a way that the lower blocking layer 302, the first photoconductive layer 303, the second photoconductive layer 304, and the surface protection layer 305 are laminated in this order.

In this case, stainless steel (SUS316L) was used as the material for the cylindrical support 132, and the members made of the solid lubrication materials (manufactured by Fuji Dice Co., Ltd.) containing the elements specified in Table 4 were fixed on the sliding surface thereof. Further, as the material for the rotation base 118-2, against which the members made of the solid lubricating material 122 were made to slide, stainless steel (SUS316L) was used; and the rotation speed of the rotation base 118-2 was set at 1 rpm. As the cleaning gas used at the time of the cleaning treatment of the interior of the reaction vessel, after completion of the deposited film formation, ClF₃ diluted with Ar (argon) gas was used. Example 5-1 is a case where the solid lubricating material contained WS₂, while Example 5-2 is a case where the solid lubricating material contained C.

In terms of one cycle consisting of the formation of a deposited film and the cleaning, 20 cycles of operation were performed under the above described conditions; thus, the deposited film forming apparatus used for the above described formation and the electrophotographic photosensitive members formed were evaluated similarly to Example 1. The evaluation results thus obtained are shown in Table 4.

TABLE 4

| | | | | Exterior | | | |
|---|---|---|---|---|---|---|---|
| | Solid | | | Appearance | Rotational | Electric | |
| | Lubricating | Sliding | Abrasion | of | Axis | Potential | Overall |
| | Material | Performance | Quantity | Bearing | Fluctuation | Uniformity | Evaluation |
| Example 5-1 | WS₂ | A | A | A | A | A | A |
| Example 5-2 | C | B | B | A | A | A | B |
| Comparative | Stainless | B | — | C | B | C | C |
| Example | steel | | | | | | |
| (rolling | | | | | | | |
| element) | | | | | | | |

As can be clearly seen from the evaluation results shown in Table 5, satisfactory results have been obtained for the sliding performance by use of the solid lubricating materials; additionally, the use of WS₂ as the solid lubricating material resulted in a more satisfactory sliding property.

### Example 6

Electrophotographic photosensitive members were formed by repeating the same procedure under the same conditions as those in Example 5 with the exception that the materials shown in Table 5 were used for the cylindrical supporting member, a material containing WS₂ (manufactured by Fuji Dice Co., Ltd.) was used as the solid lubricating material fixed to the cylindrical supporting member 132, and the materials shown in Table 5 were used for the rotation base 118-2 against which the solid lubricating material was made to slide.

In this case, for the deposited film forming apparatus used for forming the electrophotographic photosensitive members, evaluations similar to those performed in Example 5 were performed. The evaluation results thus obtained are shown in Table 5.

TABLE 5

| | | Material | | | | | | |
|---|---|---|---|---|---|---|---|---|
| | Material | for | | | Exterior | | | |
| | for | Cylindrical | | | Appearence | Rotational | Electric | |
| | Rotation | Supporting | Sliding | Abrasion | of | Axis | Potential | Overall |
| | Base | Member | Performance | Quantity | Bearing | Fluctuation | Uniformity | Evaluation |
| Example 6 | SUS | SUS | A | A | A | A | A | A |
| | Cu | SUS | A | B | A | A | A | B |
| | Ni | SUS | A | A | A | A | A | A |
| | Al | SUS | B | B | A | A | A | B |
| | SUS | Cu | A | B | A | A | A | B |
| | Cu | Cu | A | B | A | A | A | B |
| | Ni | Cu | A | B | A | A | A | B |
| | Al | Cu | B | B | A | A | A | B |
| | SUS | Ni | A | B | A | A | A | B |
| | Cu | Ni | A | B | A | A | A | B |
| | Ni | Ni | A | B | A | A | A | B |
| | Al | Ni | B | B | A | A | A | B |

* In the table, SUS, Cu and Ni signify stainless steel (SUS316L), phosphor bronze and Hastelloy, respectively.

As can be clearly seen from Table 5, even when the materials for the cylindrical supporting member 15 and the material for the rotation base were changed, satisfactory results were obtained by using the solid lubricating material for the sliding surface.

### Example 7

Electrophotographic photosensitive members were formed by repeating the same procedure under the same conditions as those in Example 5 with the exception that the electrophotographic photosensitive members were formed by using stainless steel (SUS316L) as the material for the cylindrical supporting member, a material containing WS₂ (manufactured by Fuji Dice Co., Ltd.) as the solid lubricating material fixed to the cylindrical supporting member, and stainless steel (SUS316L) as the material for the rotation base against which the solid lubricating material was made to slide; and after the electrophotographic photosensitive members were formed, a mixed gas composed of CF₄ and O₂ was used for the cleaning treatment.

In this case, for the cylindrical supporting member to which the solid lubricating material was fixed and which was used as the bearing when the electrophotographic photosensitive members were formed, the same evaluations as in Example 5 were performed. The evaluation results thus obtained are shown in Table 6 under the heading of Example 7-1.

Additionally, the evaluation results for the case where a (ClF₃+Ar) gas prepared by diluting ClF₃ gas with Ar (argon) gas was used as the cleaning gas are shown in Table 6 under the heading of Example 7-2.

TABLE 6

| | | | | Exterior | | | |
|---|---|---|---|---|---|---|---|
| | | | | Appearance | Rotational | Electric | |
| | Cleaning | Sliding | Abrasion | of | Axis | Potential | Overall |
| | Gas | Performance | Quantity | Bearing | Fluctuation | Uniformity | Evaluation |
| Example | CF₄/O₂ | A | A | A(*) | A | A | A |
| 7-1 | | | | | | | |
| Example | ClF₃ + Ar | A | A | A | A | A | A |
| 7-2 | | | | | | | |

(*)Better than the other examples as far as the exterior appearance of the bearing was concerned.

As can be clearly seen from Table 6, even when a fluorine-based cleaning gas was used in the cleaning step, satisfactory results were obtained by use of the deposited film forming apparatus in which the cylindrical supporting member provided with the solid lubricating material was used as the bearing.

As described above, according to the present invention, by rotating the cylindrical support, introducing a source gas for deposited film formation into the reaction vessel using a source gas introduction means, heating the cylindrical support, applying a discharge energy for exciting the source gas, and forming a deposited film through plasma CVD while evacuating the interior of the reaction vessel, wherein the rotation of the cylindrical support is conducted by use of a rotation means provided with a nonrotating part comprising a sliding member having at least a sliding surface part at least a part of which is formed of a solid lubricating material, it has become possible to provide a deposited film forming method and a deposited film forming apparatus in which a smooth sliding surface can be formed, whereby the sliding performance is improved and stabilized.

Additionally, according to the deposited film forming method and the deposited film forming apparatus of the present invention, the rotation of the rotation base is not hindered by powder byproducts and broken pieces of a deposited film, the corrosion resistance and durability are sufficiently secured, so that the cylindrical support can be rotated stably and smoothly.

Additionally, according to the deposited film forming method and the deposited film forming apparatus of the present invention, the process yield can be improved and the productivity of the deposited film can be increased.

Furthermore, according to the deposited film forming method and the deposited film forming apparatus of the present invention, without adversely affecting the deposited film forming apparatus itself and the electric characteristics of the deposited film, the quality of the formed deposited film is improved and the deposited film excellent in uniformity in film thickness as well as film characteristics can be obtained, so that it becomes possible to obtain satisfactory electrophotographic photosensitive members in which image defects are decreased and a high image quality is secured.

What is claimed is:

1. A deposited film forming method, which comprises disposing a cylindrical support in a pressure-reducible reaction vessel, rotating the cylindrical support, introducing a source gas for deposited film formation into the reaction vessel using a source gas introduction means, heating the cylindrical support, applying a discharge energy for exciting the source gas, and forming a deposited film through plasma CVD while evacuating the interior of the reaction vessel, wherein the rotation of the cylindrical support is conducted by use of a rotation means provided with a nonrotating part comprising a sliding member having at least a sliding surface part at least a part of which is formed of a solid lubricating material.

2. The deposited film forming method according to claim 1, wherein the sliding member has a cylindrical shape.

3. The deposited film forming method according to claim 1, further comprising, after the formation of the deposited film, a cleaning treatment using a fluorine-based cleaning gas.

4. The deposited film forming method according to claim 3, wherein the fluorine-based cleaning gas comprises at least one of chlorine (Cl) element and carbon (C) element.

5. The deposited film forming method according to claim 4, wherein the fluorine-based cleaning gas comprises at least one of ClF₃ and CF₄.

6. A deposited film forming apparatus which comprises a pressure-reducible reaction vessel, a setting means for setting a cylindrical support in the reaction vessel, a rotation means for rotating the cylindrical support, an introduction means for introducing a source gas for deposited film formation into the reaction vessel, a heating means for heating the cylindrical support, an application means for applying a discharge energy for exciting the source gas, and an evacuation means for evacuating the interior of the reaction vessel, wherein the rotation means comprises a rotating part, and a nonrotating part comprising a sliding member having at least a sliding surface part, and a solid lubricating material is provided in at least a portion of the sliding surface part.

7. The deposited film forming apparatus according to claim 6, wherein the sliding member has a cylindrical shape.

8. The deposited film forming apparatus according to claim 6, wherein the solid lubricating material comprises at least one of tungsten (W) element and sulfur (S) element.

9. The deposited film forming apparatus according to claim 6, wherein the material of the rotating part sliding on the solid lubricating material comprises at least one selected from the group consisting of stainless steel, copper, nickel and alloys thereof.

10. The deposited film forming apparatus according to claim 8, wherein the material of the rotating part sliding on the solid lubricating material comprises at least one selected from the group consisting of stainless steel, copper, nickel and alloys thereof.

11. The deposited film forming apparatus according to claim 6, wherein the introduction means is capable of introducing a fluorine-based cleaning gas into the interior of the reaction vessel.

12. The deposited film forming apparatus according to claim 6, wherein the sliding member is comprised of a solid lubricating material.

13. The deposited film forming apparatus according to claim 6, wherein the sliding member comprises a supporting member, and a plurality of members comprised of the solid lubricating material and provided at intervals therebetween on a sliding surface of the supporting member.

14. The deposited film forming apparatus according to claim 13, wherein the supporting member comprises at least one selected from the group consisting of stainless steel, copper, nickel and alloys thereof.
